(19) United States
(12) Patent Application Publication
(10) Pub. No.: US 2013/0037824 A1
(43) Pub. Date: Feb. 14, 2013

(54) POWER SEMICONDUCTOR DEVICE

(71) Applicants: Hideki HAYASHI, Osaka-shi (JP); Nobuo Shiga, Osaka-shi (JP)

(72) Inventors: Hideki HAYASHI, Osaka-shi (JP); Nobuo Shiga, Osaka-shi (JP)

(73) Assignee: Sumitomo Electric Industries, Ltd., Osaka-shi (JP)

(21) Appl. No.: 13/557,695

(22) Filed: Jul. 25, 2012

Related U.S. Application Data
(60) Provisional application No. 61/522,385, filed on Aug. 11, 2011.

(30) Foreign Application Priority Data
Aug. 11, 2011 (JP) 2011-175472

(51) Int. Cl. H01L 29/165

(52) U.S. Cl. 257/77; 257/E29.085

(57) ABSTRACT

Cell electrodes are provided respectively for cell structures on a semiconductor substrate. The cell electrodes are divided into groups each including two or more cell electrodes. Conductive members are respectively electrically connected to the groups. The conductive members have a used portion and an unused portion. The used portion has two or more conductive members electrically connected to each other. The unused portion has at least one of the conductive members and is electrically insulated from the used portion.

### BACKGROUND OF THE INVENTION

1. Field of the Invention

The present invention relates to a power semiconductor device, in particular, a power semiconductor device having cell structures.

2. Description of the Background Art

In recent years, semiconductor devices have been developed each of which employs a substrate made of silicon carbide (SiC) or gallium nitride (GaN) instead of silicon (Si). As compared with a Si substrate, each of such SiC substrate and GaN substrate has a difficulty in securing both crystal quality and substrate size. Accordingly, when forming a large substrate, defects are likely to be included therein. For example, it is well known that a SiC substrate is likely to have crystal defects called “micro pipes”.

A power semiconductor device frequently handles a current larger than that handled by a normal semiconductor device, and frequently requires a relatively large substrate. Such a substrate tends to have defects due to the reason described above. This likely results in decreased yield. To address this, there has been examined a method for securing a yield for semiconductor devices each having a large SiC substrate or GaN substrate.

For example, according to U.S. Pat. No. 6,514,779, first, a plurality of silicon carbide devices of the same type are formed on a silicon carbide wafer in a predetermined pattern. Next, among the plurality of silicon carbide devices, devices having passed an electric test are connected to one another.

When simply applying the technique in the specification of the above-described US Patent to power semiconductor devices having conventional cell structures, it is considered that cell structures having passed the electric test are connected to one another. However, in the case where the number of cells are very large or where the size of each cell is very small, it is difficult to determine for each cell whether to make electrical connection and it is difficult to make the electrical connection.

### SUMMARY OF THE INVENTION

The present invention has been made in view of the foregoing problem, and has its object to provide a power semiconductor device that can be readily manufactured while suppressing yield from being decreased due to defects of its substrate.

A power semiconductor device of the present invention has a plurality of cell structures, and includes a semiconductor substrate, a common electrode, a plurality of cell electrodes, and a plurality of conductive members. The semiconductor substrate is made of one of silicon carbide and gallium nitride. The common electrode is provided on the semiconductor substrate as an electrode for each of the plurality of cell structures. The plurality of cell electrodes are provided respectively for the plurality of cell structures on the semiconductor substrate. The plurality of cell electrodes are divided into a plurality of groups each including two or more cell electrodes. The plurality of conductive members are respectively electrically connected to the plurality of groups. The plurality of conductive members include a used portion and an unused portion. The used portion has two or more conductive members electrically connected to each other. The unused portion has at least one of the plurality of conductive members and is electrically insulated from the used portion.

According to this power semiconductor device, the used portion and the unused portion are electrically insulated from each other. Hence, the used portion can be used whereas the unused portion are not be used. In this way, even if a cell electrode belonging to the group connected to the conductive member of the unused portion has a deficiency resulting from a defect of the semiconductor substrate, this deficiency can be avoided from affecting the power semiconductor device.

Further, according to this power semiconductor device, each of the groups of the plurality of conductive members electrically connected to each other includes two or more cell electrodes. Accordingly, by making selection for each of the conductive members as to whether to include it in the used portion, two or more cell electrodes for each group can collectively undergo the selection as to whether to include them in the used portion. This leads to simplified process as compared with a case of making individual selection for each cell electrode as to whether to include it in the used portion.

Preferably, the power semiconductor device includes a terminal portion electrically connected to each of the plurality of conductive members in the used portion. Accordingly, by using the terminal portion, the used portion can be used whereas the unused portion is not used.

Preferably in the power semiconductor device, the terminal portion and each of the plurality of conductive members of the used portion are connected to each other by wire bonding. Accordingly, determination can be readily made for the conductive member as to whether to include it in the used portion, by performing or not performing the wire bonding.

Preferably in the power semiconductor device, the terminal portion and each of the plurality of conductive members of the used portion are connected to each other by a solder ball. Accordingly, determination can be readily made for the conductive member as to whether to include it in the used portion, by disposing or not disposing the solder ball.

Preferably in the power semiconductor device, the at least one of the plurality of conductive members in the unused portion is covered with an insulator. Accordingly, more secure electric insulation can be achieved between the unused portion and the used portion.

Preferably, the power semiconductor device includes a plurality of gate electrodes provided to respectively correspond to the plurality of groups. The plurality of gate electrodes include a controlled portion and an uncontrolled portion. The controlled portion has two or more gate electrodes electrically connected to each other. The uncontrolled portion has at least one of the plurality of gate electrodes and is electrically insulated from the controlled portion.

Accordingly, the controlled portion and the uncontrolled portion are electrically insulated from each other. Hence, the controlled portion can be used whereas the uncontrolled portion is not used. Accordingly, even if a gate electrode in the uncontrolled portion has a deficiency resulting from a defect of the semiconductor substrate, this deficiency can be avoided from affecting the power semiconductor device.

As apparent from the description above, according to the present invention, a power semiconductor device can be readily manufactured while suppressing yield from being decreased due to defects of its substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view schematically showing a configuration of a power semiconductor device in a first embodiment of the present invention.

FIG. 2 is a circuit diagram schematically showing the configuration of the power semiconductor device of FIG. 1.

FIG. 3 is a cross sectional view schematically showing a configuration of a power semiconductor device in a second embodiment of the present invention.

FIG. 4 is a cross sectional view schematically showing a first step of a method for manufacturing the power semiconductor device in FIG. 4.

FIG. 5 is a cross sectional view schematically showing a second step of the method for manufacturing the power semiconductor device in FIG. 4.

FIG. 6 is a cross sectional view schematically showing a variation of the step of FIG. 5.

FIG. 7 is a plan view schematically showing a configuration of a power semiconductor device in a third embodiment of the present invention.

FIG. 8 is a plan view schematically showing one step of the method for manufacturing the power semiconductor device in FIG. 7.

FIG. 9 is a circuit diagram schematically showing a configuration of a power semiconductor device in a fourth embodiment of the present invention.

FIG. 10 is a plan view schematically showing configurations of a plurality of conductive members provided in the power semiconductor device of FIG. 9.

FIG. 11 is a plan view schematically showing configurations of a plurality of gate electrodes provided in the power semiconductor device of FIG. 9.

FIG. 12 is a cross sectional view schematically showing cell structures provided in the power semiconductor device of FIG. 9.

FIG. 13 is a plan view schematically showing a layout of impurity regions in a semiconductor substrate of the power semiconductor device of FIG. 9.

FIG. 14 is a cross sectional view schematically showing an inter-element separating structure in a power semiconductor device of a fifth embodiment of the present invention.

### DESCRIPTION OF THE PREFERRED EMBODIMENTS

The following describes embodiments of the present invention with reference to figures.

### First Embodiment

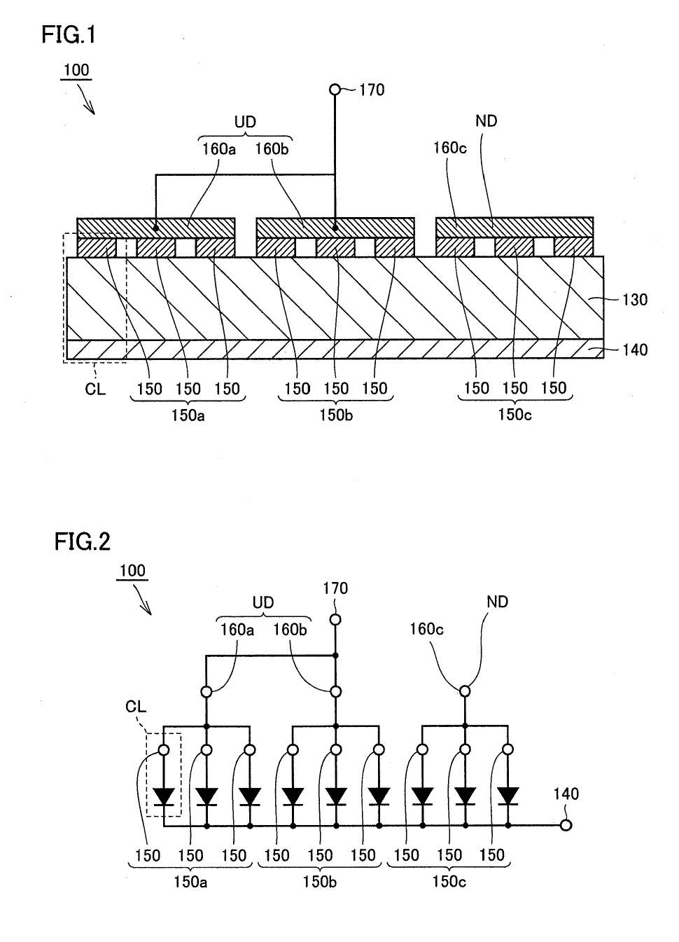

As shown in FIG. 1 and FIG. 2, a power semiconductor device 100 of the present embodiment includes a plurality of cell structures CL each serving as a Schottky barrier diode. The plurality of cell structures CL are electrically connected to one another in parallel. Power semiconductor device 100 includes a semiconductor substrate 130, a cathode electrode 140 (common electrode), a plurality of anode electrodes 150 (a plurality of cell electrodes), conductive members 160a-160c, and a terminal portion 170.

Semiconductor substrate 130 is made of one of silicon carbide and gallium nitride. It should be noted that semiconductor substrate 130 may have a multilayer structure, and is preferably adapted to have an impurity concentration relatively lower at the side where a Schottky barrier is to be formed.

Cathode electrode 140 is an ohmic electrode, and is provided on semiconductor substrate 130 (the bottom surface thereof in FIG. 1) as an electrode for each of the plurality of cell structures CL.

The plurality of anode electrodes 150 are provided respectively for the plurality of cell structures CL on semiconductor substrate 130 (the upper surface thereof in FIG. 1). The plurality of anode electrodes 150 are divided into groups 150a-150c each including two or more anode electrodes 150.

Conductive members 160a-160c are respectively connected to groups 150a-150c. Specifically, conductive members 160a-160c are formed in contact with the plurality of anode electrodes 150 belonging to groups 150a-150c.

Conductive members 160a-160c have a used portion UD and an unused portion ND. Used portion UD has two or more conductive members 160a and 160b electrically connected to each other. Unused portion ND has conductive member 160c, which is at least one of conductive members 160a-160c. Used portion UD and unused portion ND are electrically insulated from each other.

Terminal portion 170 is electrically connected to each of conductive members 160a and 160b of used portion UD. Conductive member 160c of unused portion ND is electrically insulated from terminal portion 170.

The following describes a method for manufacturing power semiconductor device 100.

First, cathode electrode 140, anode electrodes 150, and conductive members 160a-160c are formed on semiconductor substrate 130. At this point, it has not been determined yet whether each of conductive members 160a-160c belongs to used portion UD or unused portion ND.

Next, an electric characteristics test is conducted between each of conductive members 160a-160c and cathode electrode 140. For example, a value of leakage current is measured when applying a predetermined reverse voltage between each of conductive members 160a-160c and cathode electrode 140.

If electric characteristics between conductive member 160c and cathode electrode 140 fail to meet a standard as a result of the test for example, conductive member 160c is included in unused portion ND, and the other conductive members 160a and 160b are included in used portion UD. In other words, conductive members 160a and 160b are electrically connected to each other, whereas conductive members 160a and 160b are not electrically connected to conductive member 160c.

In this way, power semiconductor device 100 is obtained.

According to power semiconductor device 100 of the present embodiment, used portion UD and unused portion ND are electrically insulated from each other. Hence, used portion UD can be used whereas unused portion ND are not used. In this way, even if an anode electrode 150 belonging to group 150c connected to conductive member 160c of unused portion ND has a deficiency resulting from a defect of semiconductor substrate 130, this deficiency can be avoided from affecting power semiconductor device 100.

In addition, according to this power semiconductor device 100, two or more anode electrodes 150 are included in each of the groups (groups 150a-150c) electrically connected to conductive members 160a-160c. Accordingly, by making selection for each of conductive members 160a-160c as to whether to include it in used portion UD, two or more anode electrodes 150 in each group can collectively undergo the selection as to whether to include them in used portion UD. This leads to simplified process as compared with a case of making individual selection for each of anode electrodes 150 as to whether to include it in used portion UD.

Specifically, wiring can be simplified as compared with a case of wiring each anode electrode 150 to terminal portion 170 individually. Further, each of conductive members 160a and 160c to be wired can be formed larger than each of anode electrodes 150. This facilitates the wiring.

It has been illustrated in the present embodiment that three conductive members 160a-160c are provided. In this case, at least about ⅓ of the substrate is not substantially used. In order to reduce a ratio of the unused portion of the substrate, a larger number of conductive members may be provided.

Further, FIG. 1 shows that three anode electrodes 150 are provided for each of groups 150a-150c, but a larger number of cell electrodes may belong to each of the groups.

Further, in the case where the number of conductive members meeting the standard for electric characteristics is larger than the designed number of conductive members for used portion UD in power semiconductor device 100, a part of the conductive members meeting the standard may be included in unused portion ND. In this way, a predetermined number of conductive members can be included in used portion UD.

### Second Embodiment

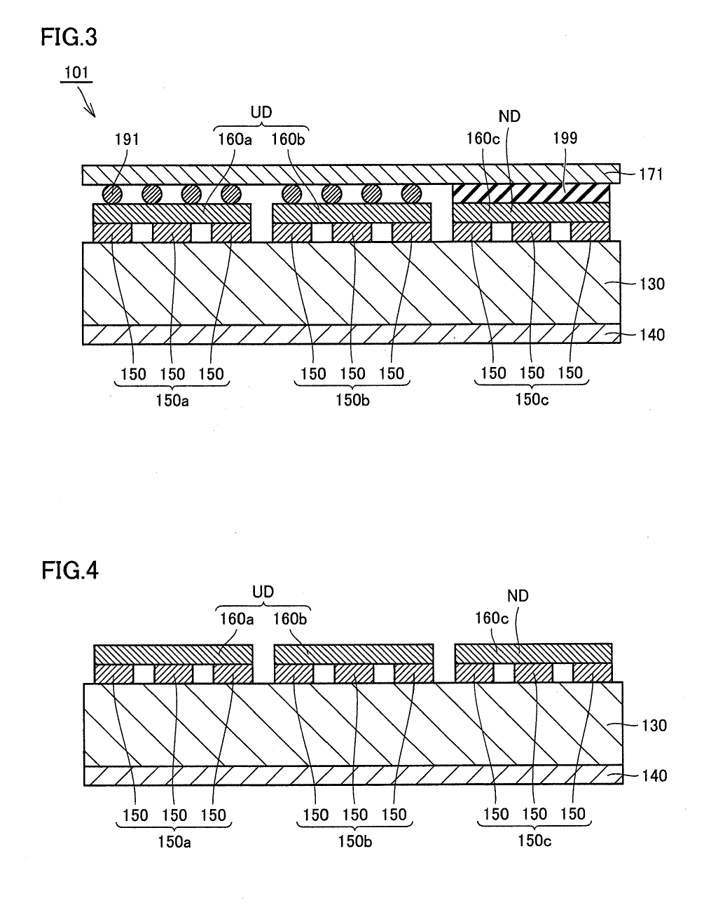

As shown in FIG. 3, a power semiconductor device 101 of the present embodiment has a wiring board 171 (terminal portion), solder balls 191, and an insulator portion 199. Wiring board 171 corresponds to terminal portion 170 in the first embodiment, and is a metal plate, for example.

On each of conductive members 160a and 160b of used portion UD, solder balls 191 are provided. Accordingly, solder balls 191 provide connection between wiring board 171 and each of conductive members 160a and 160b of used portion UD.

Meanwhile, no solder balls 191 are provided on conductive member 160c of unused portion ND. Thus, wiring board 171 is not electrically connected to conductive member 160c of unused portion ND. Further, insulator portion 199 is provided on conductive member 160c of unused portion ND. Thus, unused portion ND is covered with the insulator.

The following describes a method for manufacturing power semiconductor device 101.

As shown in FIG. 4, cathode electrode 140, anode electrodes 150, and conductive members 160a-160c are formed on semiconductor substrate 130. At this point, it has not been determined yet whether each of conductive members 160a-160c belongs to used portion UD or unused portion ND.

Next, an electric characteristics test is conducted between each of conductive members 160a-160c and cathode electrode 140. For example, a value of leakage current is measured when applying a predetermined reverse voltage between each of conductive members 160a-160c and cathode electrode 140.

If electric characteristics between conductive member 160c and cathode electrode 140 fail to meet a standard as a result of the test, conductive member 160c is included in unused portion ND, and the other conductive members 160a and 160b are included in used portion UD. In other words, conductive members 160a and 160b are electrically connected to each other, whereas conductive members 160a and 160b are not electrically connected to conductive member 160c.

As shown in FIG. 5, specifically, the solder balls are disposed on conductive members 160a and 160b of conductive members 160a-160c, whereas no solder balls are disposed on conductive member 160c. Further, on conductive member 160c, insulator portion 199 is formed.

Next, via solder balls 191, wiring board 171 is connected to each of conductive members 160a and 160b.

In this way, power semiconductor device 101 is obtained.

It should be noted that configurations other than the above are substantially the same as those of the first embodiment. Hence, the same or corresponding elements are given the same reference characters and are not described repeatedly.

According to the present embodiment, function and effect similar to those of the first embodiment are obtained. Further, determination can be readily made for each of the conductive members as to whether to include it in used portion UD, by disposing or not disposing solder balls 191.

Further, insulator portion 199 allows for more secure electric insulation between unused portion ND and used portion UD. It should be noted that when such electric insulation can be secured sufficiently without insulator portion 199, insulator portion 199 can be omitted.

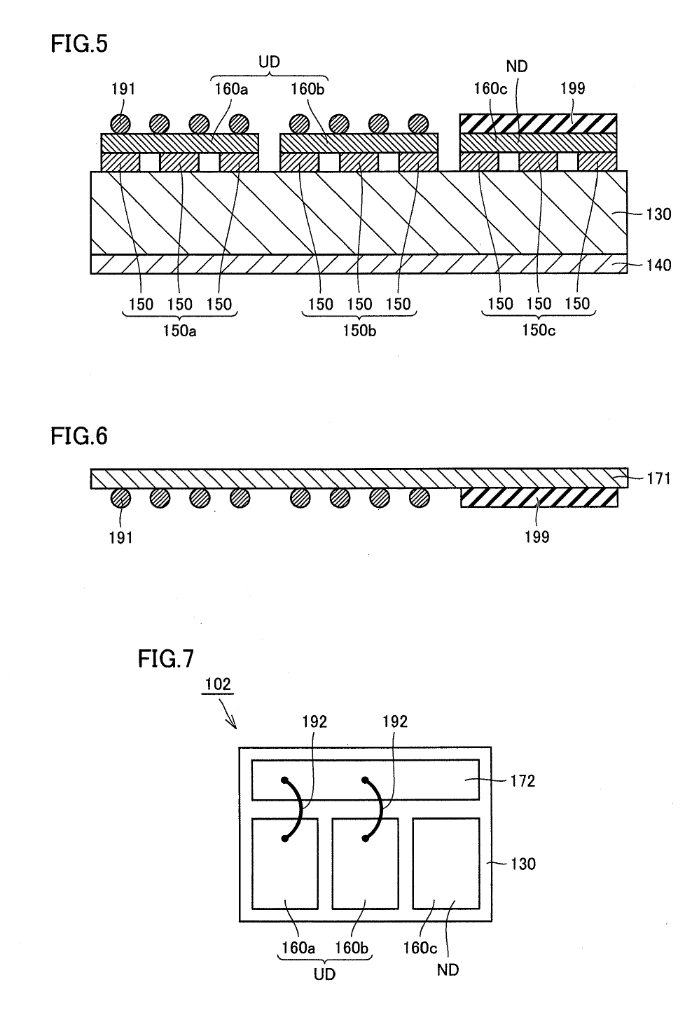

Instead of the step of FIG. 5, as shown in FIG. 6, at least one of each solder ball 191 and insulator portion 199 may be first formed on wiring board 171. Thereafter, wiring board 171 is attached onto conductive members 160a and 160b, thereby obtaining a power semiconductor device substantially the same as that of the present embodiment.

### Third Embodiment

As shown in FIG. 7, a power semiconductor device 102 of the present embodiment has a wiring pad 172 (terminal portion) and a plurality of bonding wires 192. Wiring pad 172 corresponds to terminal portion 170 in the first embodiment, and is provided above semiconductor substrate 130 with an insulating layer (not shown) interposed therebetween, for example. Each of bonding wires 192 is configured to provide connection between wiring pad 172 and each of conductive members 160a and 160b of used portion UD, by means of wire bonding.

The following describes a method for manufacturing power semiconductor device 102.

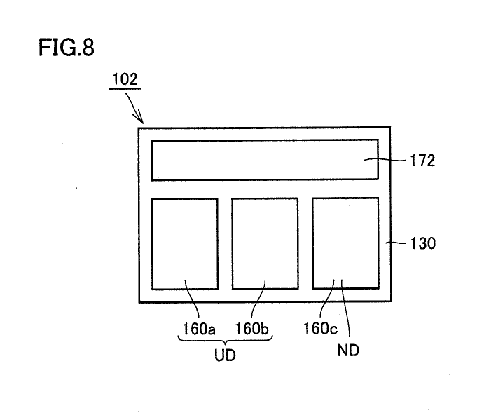

As shown in FIG. 8, conductive members 160a-160c and wiring pad 172 are formed on semiconductor substrate 130. At this point, it has not been determined yet whether each of conductive members 160a-160c belongs to used portion UD or unused portion ND.

Next, an electric characteristics test is conducted between each of conductive members 160a-160c and cathode electrode 140 (not shown in FIG. 8). For example, a value of leakage current is measured when applying a predetermined reverse voltage between each of conductive members 160a-160c and cathode electrode 140.

If electric characteristics between conductive member 160c and cathode electrode 140 fail to meet a standard as a result of the test, conductive member 160c is included in unused portion ND, and the other conductive members 160a and 160b are included in used portion UD. In other words, conductive members 160a and 160b are electrically connected to each other, whereas conductive members 160a and 160b are not electrically connected to conductive member 160c.

Specifically, bonding wire 192 is connected onto each of conductive members 160a and 160b of conductive members 160a-160c, whereas no bonding wire 192 is connected onto conductive member 160c.

In this way, power semiconductor device 102 is obtained.

It should be noted that configurations other than the above are substantially the same as those of the first embodiment. Hence, the same or corresponding elements are given the same reference characters and are not described repeatedly.

According to the present embodiment, function and effect similar to those of the first embodiment are obtained. Further, determination can be readily made for each of the conductive members as to whether to include it in used portion UD, by connecting or not connecting bonding wires 192.

### Fourth Embodiment

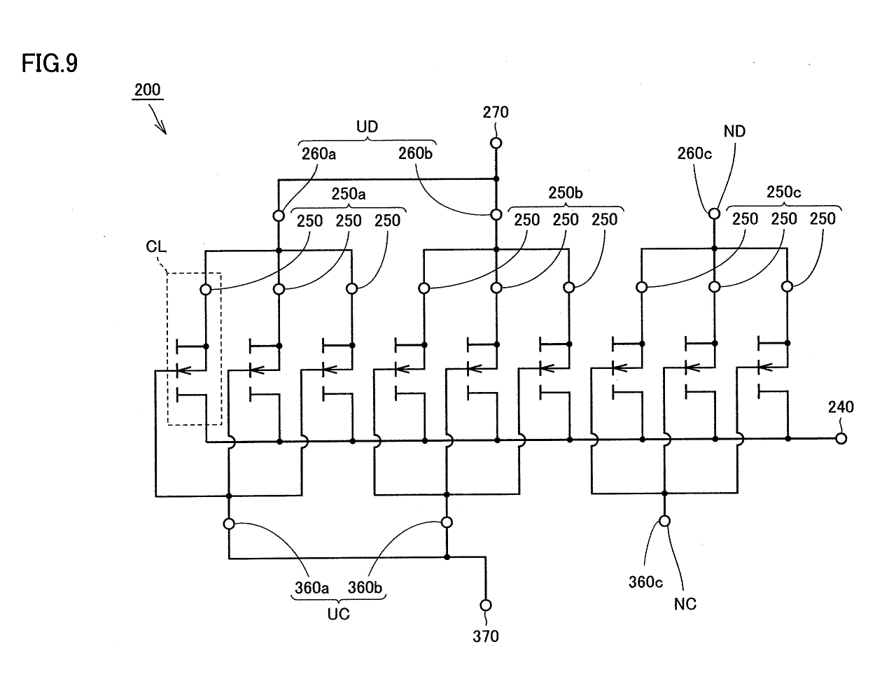

As shown in FIG. 9, a power semiconductor device 200 of the present embodiment is a MISFET (Metal Insulator Semiconductor Field Effect Transistor). Power semiconductor device 200 has a plurality of cell structures CL each serving as a MISFET. The plurality of cell structures CL are electrically connected to one another in parallel. It should be noted that power semiconductor device 200 can employ an oxide film as its gate insulating film. In this case, power semiconductor device 200 is a MOSFET (Metal Oxide Semiconductor Field Effect Transistor). Further, in the present embodiment, power semiconductor device 200 is a vertical type DiMOSFET (Double Implanted MOSFET).

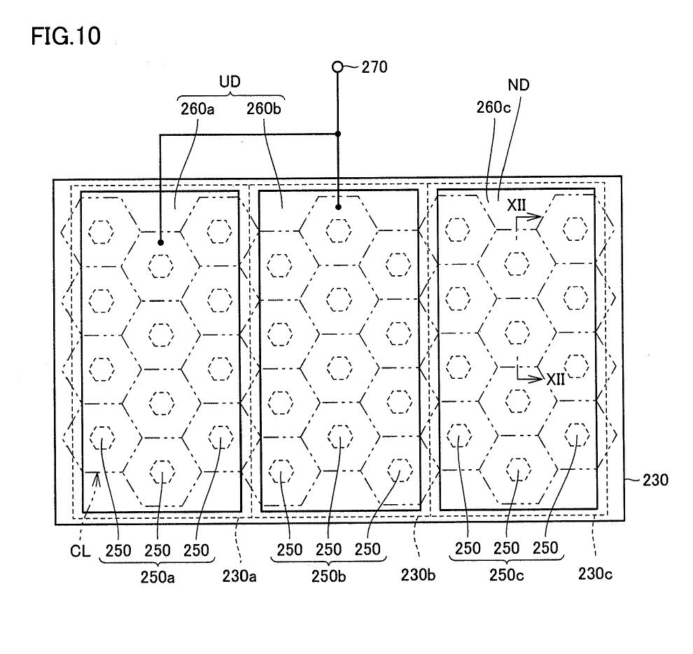

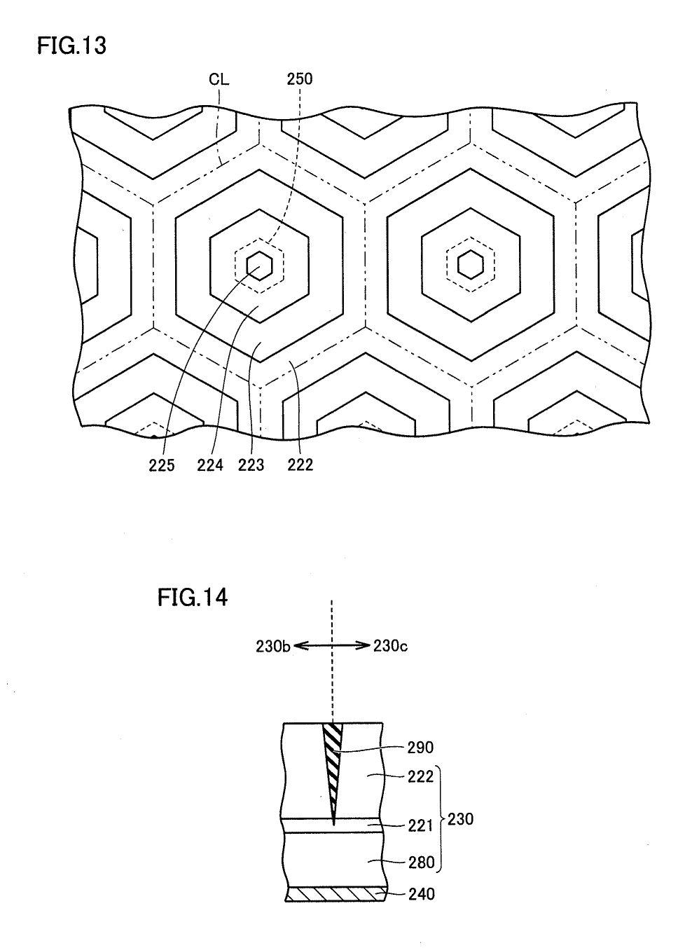

Further, as shown in FIG. 10 to FIG. 13, in the present embodiment, each of cell structures CL has a substantially regular hexagonal shape when viewed in a plan view. Power semiconductor device 200 has a semiconductor substrate 230, a drain electrode 240 (common electrode), a plurality of source electrodes 250, conductive members 260a-260c, gate electrodes 360a-360c, a terminal portion 270, a terminal portion 370, a gate insulating film 226, and an interlayer insulating film 227.

Drain electrode 240 (FIG. 12) is an ohmic electrode, and is provided on semiconductor substrate 230 (the bottom surface thereof in FIG. 12) as an electrode for each of the plurality of cell structures CL.

The plurality of source electrodes 250 are provided respectively for the plurality of cell structures CL (FIG. 10) on semiconductor substrate 230 (the upper surface thereof in FIG. 12). The plurality of source electrodes 250 are divided into a groups 250a-250c each including two or more source electrodes 250.

Conductive members 260a-260c are respectively electrically connected to groups 250a-250c. Specifically, conductive members 260a-260c are formed in contact with the plurality of source electrodes 250 belonging to groups 250a-250c. Conductive members 260a-260c have a used portion UD and an unused portion ND. Used portion UD has two or more conductive members 260a and 260b electrically connected to each other. Unused portion ND has conductive member 260c, which is at least one of conductive members 260a-260c. Used portion UD and unused portion ND are electrically insulated from each other.

Terminal portion 270 is electrically connected to each of conductive members 260a and 260b of used portion UD. Conductive member 260c of unused portion ND is electrically insulated from terminal portion 270.

Gate electrodes 360a-360c are provided to correspond to groups 250a-250c, respectively. Gate electrodes 360a-360c are separated from one another. Gate electrodes 360a-360c have a controlled portion UC and an uncontrolled portion NC. Controlled portion UC has two or more gate electrodes 360a and 360b electrically connected to each other. Uncontrolled portion NC has gate electrode 360c, which is at least one of gate electrodes 360a-360c. Controlled portion UC and uncontrolled portion NC are electrically insulated from each other.

Terminal portion 370 is electrically connected to each of gate electrodes 360a and 360b of controlled portion UC. Gate electrode 360c of uncontrolled portion NC is electrically insulated from terminal portion 370.

Semiconductor substrate 230 (FIG. 12) is made of one of silicon carbide and gallium nitride. Semiconductor substrate 230 includes a single-crystal substrate 280, a buffer layer 221, a breakdown voltage holding layer 222, p regions 223, n⁺ regions 224, and p⁺ regions 225.

Each of single-crystal substrate 280 and buffer layer 221 has n type conductivity. Buffer layer 221 contains a conductive impurity of n type at a concentration of, for example, 5×10¹⁷ cm⁻³. Buffer layer 221 has a thickness of, for example, 0.5 μm.

Breakdown voltage holding layer 222 is formed on buffer layer 221, and is made of silicon carbide with n type conductivity. For example, breakdown voltage holding layer 222 has a thickness of 10 μm, and includes a conductive impurity of n type at a concentration of 5×10¹⁵ cm⁻³.

Semiconductor substrate 230 has an upper surface in which the plurality of p regions 223 of p type conductivity are formed with a space therebetween. In the upper surface thereof, each of n⁺ regions 224 is formed within each of p regions 223. Further, each of p⁺ regions 225 is formed to extend from the upper surface to p region 223 through n⁺ region 224. In the upper surface, each of p regions 223 has a channel region sandwiched between n⁺ region 224 and breakdown voltage holding layer 222 and covered with each of gate electrodes 360a-360c with a gate insulating film 226 interposed therebetween.

Gate insulating film 226 is formed on the upper surface of semiconductor substrate 230 at an exposed portion of breakdown voltage holding layer 222 between the plurality of p regions 223. Specifically, gate insulating film 226 is formed to extend on n⁺ region 224 in one p region 223, p region 223, the exposed portion of breakdown voltage holding layer 222 between the two p regions 223, the other p region 223, and n⁺ region 224 in the other p region 223. On gate insulating film 226, each of gate electrodes 360a-360c is formed. Further, source electrodes 250 are formed on n⁺ regions 224 and p⁺ regions 225. On each of source electrodes 250, one of conductive members 260a-260c is formed. Conductive members 260a-260c are respectively disposed on regions 230a-230c (FIG. 10) of semiconductor substrate 230.

According to power semiconductor device 200 of the present embodiment, used portion UD and unused portion ND are electrically insulated from each other. Hence, used portion UD can be used whereas unused portion ND are not used. In this way, even if a source electrode 250 belonging to group 250c connected to conductive member 260c of unused portion ND has a deficiency resulting from a defect of semiconductor substrate 230, this deficiency can be avoided from affecting power semiconductor device 200.

In addition, according to this power semiconductor device 200, two or more source electrodes 250 are included in each of the groups (groups 250a-250c) electrically connected to conductive members 260a-260c. Accordingly, by making selection for each of conductive members 260a-260c as to whether to include it in used portion UD, two or more source electrodes 250 in each group can collectively undergo the selection as to whether to include them in used portion UD. This leads to simplified process as compared with a case of making individual selection for each source electrode 250 as to whether to include it in used portion UD. Specifically, wiring can be simplified as compared with a case of wiring each source electrode 250 to terminal portion 270 individually. Further, each of conductive members 260a and 260c to be wired can be formed larger than each of source electrodes 250. This facilitates the wiring.

Further, controlled portion UC and uncontrolled portion NC are electrically insulated from each other. Hence, controlled portion UC can be used whereas uncontrolled portion NC is not used. In this way, even if gate electrode 360c of uncontrolled portion NC has a deficiency resulting from a defect of semiconductor substrate 230, this deficiency can be avoided from affecting power semiconductor device 200.

In the present embodiment, each of cell structures CL has a substantially regular hexagonal shape, but the cell structure may have a different shape such as a rectangular shape or a square shape.

### Fifth Embodiment

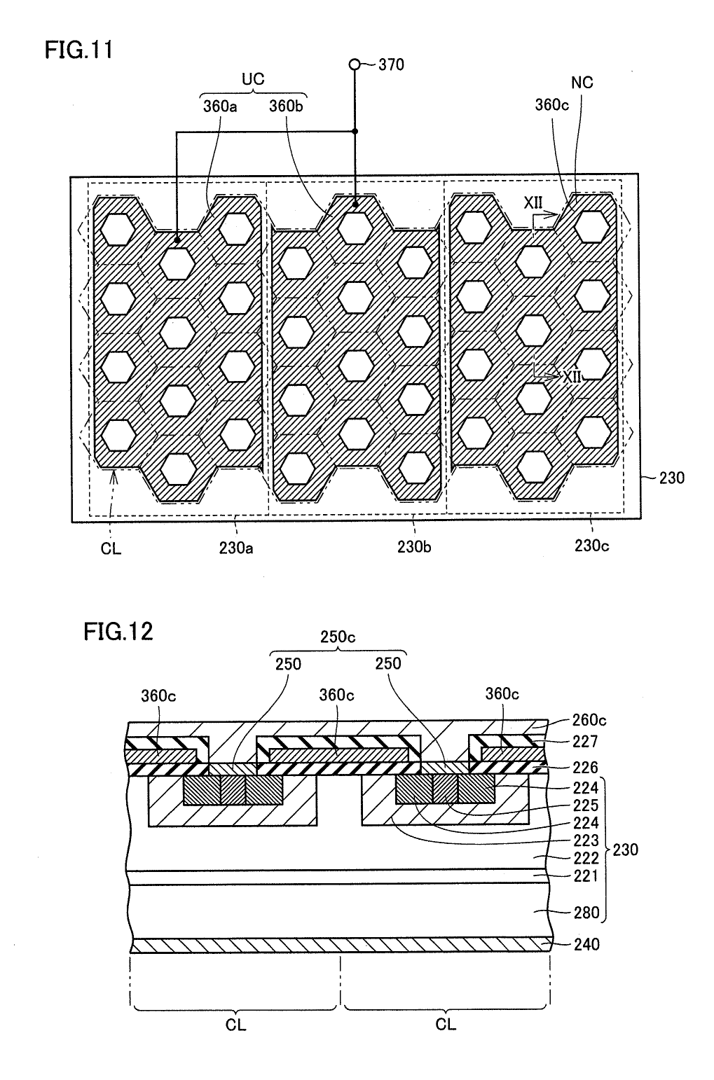

As shown in FIG. 14, in a power semiconductor device of the present embodiment, at the upper surface side of semiconductor substrate 230, inter-element separating structures 290 are provided at boundaries among regions 230a-230c (FIG. 10 and FIG. 11) of semiconductor substrate 230. Each of inter-element separating structures 290 is, specifically, a trench portion in which an insulator is embedded.

It should be noted that configurations other than the above are substantially the same as those of the fourth embodiment. Hence, the same or corresponding elements are given the same reference characters and are not described repeatedly.

According to the present embodiment, even if a leakage current path is formed to extend through a defect in region 230c for example, an influence thereof can be restrained from extending to region 230b adjacent to region 230c.

It should be noted that the description above has illustrated the diode and the MOSFET as the power semiconductor device, but the power semiconductor device is not limited to these. The power semiconductor device may be a JFET (Junction FET), for example. Also in the description above, the vertical type power semiconductor devices have been illustrated as the power semiconductor device, but the power semiconductor device is not limited to these and may be a lateral type power semiconductor device.

Although the present invention has been described and illustrated in detail, it is clearly understood that the same is by way of illustration and example only and is not to be taken by way of limitation, the scope of the present invention being interpreted by the terms of the appended claims.

1. A power semiconductor device having a plurality of cell structures, comprising:
a semiconductor substrate made of one of silicon carbide and gallium nitride;
a common electrode provided on said semiconductor substrate as an electrode for each of said plurality of cell structures;
a plurality of cell electrodes provided respectively for said plurality of cell structures on said semiconductor substrate, said plurality of cell electrodes being divided into a plurality of groups each including two or more said cell electrodes; and
a plurality of conductive members respectively electrically connected to said plurality of groups, said plurality of conductive members including a used portion, which has two or more said conductive members electrically connected to each other, and an unused portion, which has at least one of said plurality of conductive members and is electrically insulated from said used portion; and
a terminal portion electrically connected to each of said plurality of conductive members in said used portion, wherein
said at least one of said plurality of conductive members in said unused portion is covered with an insulator separated from said plurality of conductive members of said used portion.

2. (canceled)

3. (canceled)

4. The power semiconductor device according to claim 1, wherein said terminal portion and each of said plurality of conductive members of said used portion are connected to each other by a solder ball.

5. (canceled)

6. The power semiconductor device according to claim 1, further comprising a plurality of gate electrodes provided to respectively correspond to said plurality of groups, wherein
said plurality of gate electrodes include a controlled portion, which has two or more said gate electrodes electrically connected to each other, and an uncontrolled portion, which has at least one of said plurality of gate electrodes and is electrically insulated from said controlled portion.

7. A method for manufacturing a power semiconductor device having a plurality of cell structures, comprising the steps of:
providing a plurality of cell electrodes respectively for said plurality of cell structures on a semiconductor substrate made of one of silicon carbide and gallium nitride;
forming a plurality of conductive members respectively electrically connected to a plurality of groups each including two or more of said cell electrodes;
forming an insulator on a terminal portion; and
attaching said terminal portion on said plurality of conductive members after the step of forming said insulator, the step of attaching said terminal portion being performed such that said terminal portion is electrically connected to two or more of said plurality of conductive members and is insulated by said insulator from at least one thereof.

8. The method for manufacturing the power semiconductor device according to claim 7, wherein the step of attaching said terminal portion includes the step of connecting said terminal portion and each of said two or more of said plurality of conductive members to each other by a solder ball.

9. The method for manufacturing the power semiconductor device according to claim 8, further comprising the step of forming said solder ball on said terminal portion before the step of attaching said terminal portion.
